(19) United States
(12) Patent Application Publication
(10) Pub. No.: US 2026/0073960 A1
(43) Pub. Date: Mar. 12, 2026

(54) CHANGE IN CLOCK FREQUENCY OF SEMICONDUCTOR DEVICE AND SEMICONDUCTOR SYSTEM

(71) Applicant: SK hynix Inc., Icheon-si Gyeonggi-do (KR)

(72) Inventors: Ji Hwan PARK, Icheon-si Gyeonggi-do (KR); Se Ra JEONG, Icheon-si Gyeonggi-do (KR); Ha Jun JEONG, Icheon-si Gyeonggi-do (KR)

(73) Assignee: SK hynix Inc., Icheon-si Gyeonggi-do (KR)

(21) Appl. No.: 19/040,190

(22) Filed: Jan. 29, 2025

(30) Foreign Application Priority Data
Sep. 11, 2024 (KR) 10-2024-0124184

(51) Int. Cl. G11C 7/22; G11C 7/20

(52) U.S. Cl. CPC G11C 7/222; G11C 7/20

(57) ABSTRACT

A first semiconductor device provides a system clock signal and a command address signal to a second semiconductor device. The first semiconductor device provides a command address signal related to a clock frequency change to the second semiconductor device. The second semiconductor device changes a frequency mode after entering a low power mode.

### CROSS-REFERENCES TO RELATED APPLICATION

This application claims priority under 35 U.S.C. § 119 (a) to Korean Patent Application No. 10-2024-0124184, filed in the Korean Intellectual Property Office on Sep. 11, 2024, the entire contents of which application is incorporated herein by reference.

### BACKGROUND

### 1. Technical Field

The present application relates to the design and operation of integrated circuits, including but not limited to clocking of semiconductor devices.

### 2. Related Art

An electronic device includes many electronic components. Among the electronic components, a computer system includes a plurality of semiconductor systems. The semiconductor system may include many semiconductor devices including a semiconductor. The semiconductor devices that constitute the semiconductor system communicate with each other by transmitting and receiving system clock signals, such as an external clock signal, and data. The semiconductor devices operate in synchronization with clock signals having various frequency bands. A memory device, of the semiconductor system may be compatible with various operating frequencies and may change the operating frequency of the memory device based on a command address signal provided by a host device or a memory controller such that the memory device can operate in synchronization with clock signals having various frequency bands.

### SUMMARY

In an embodiment, a method of changing a clock frequency may include providing, by a first semiconductor device, a system clock signal at a first frequency and a command address signal related to a clock frequency change to a second semiconductor device. The method may include changing, by the second semiconductor device, a frequency mode based on the command address signal related to the clock frequency change after entering a low power mode. The method may include providing, by the first semiconductor device, the system clock signal at a second frequency to the second semiconductor device.

In an embodiment, a semiconductor device may include an internal clock generation circuit and a command address control circuit. The internal clock generation circuit may be configured to receive a system clock signal, configured to operate in one of a high frequency mode and a low frequency mode based on a frequency mode signal, and configured to generate a command clock signal from the system clock signal. The command address control circuit may be configured to receive a command address signal, configured to generate the frequency mode signal based on the command address signal, and configured to generate the frequency mode signal after the semiconductor device enters a low power mode.

In an embodiment, a semiconductor device may include an internal clock generation circuit and a command address control circuit. The internal clock generation circuit may be configured to receive a system clock signal and generate a command clock signal from the system clock signal in response to operating in one of a high frequency mode and a low frequency mode. The command address control circuit may be configured to receive the command address signal related to a clock frequency change, configured to change a frequency mode of the internal clock generation circuit, and configured to delay frequency mode change time of the internal clock generation circuit until the semiconductor device enters a low power mode.

### BRIEF DESCRIPTION OF THE DRAWINGS

FIG. 1 is a diagram illustrating a semiconductor system according to an embodiment of the present disclosure.

FIG. 2 is a flowchart illustrating operation of the semiconductor system according to an embodiment of the present disclosure.

FIG. 3 is a diagram illustrating a semiconductor device according to an embodiment of the present disclosure.

FIG. 4 is a diagram illustrating an embodiment of a clock driver according to an embodiment of the present disclosure.

FIG. 5 is a diagram illustrating an embodiment of a command clock generation circuit according the present disclosure.

FIG. 6 is a diagram illustrating an embodiment of a data clock generation circuit according to an embodiment of the present disclosure.

FIG. 7 is a diagram illustrating an embodiment of a mode register circuit according to the present disclosure.

FIG. 8 is a timing diagram illustrating operation of a semiconductor system according to an embodiment of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

When one element is identified as “coupled” to another element, the elements may be coupled directly or through an intervening element between the elements. When two elements are identified as “directly coupled,” one element is directly coupled to the other element without an intervening element between the two elements.

In a semiconductor system in which a single system clock signal is used, a memory device generates an internal clock signal to receive a command address signal and an internal clock signal to receive and transmit data from the single system clock signal. In this example, when the memory device immediately changes the clock signal frequency in response to a command address signal related to a clock frequency change before the frequency of the system clock signal is changed, a malfunction in which the memory device does not receive the system clock signal normally may occur.

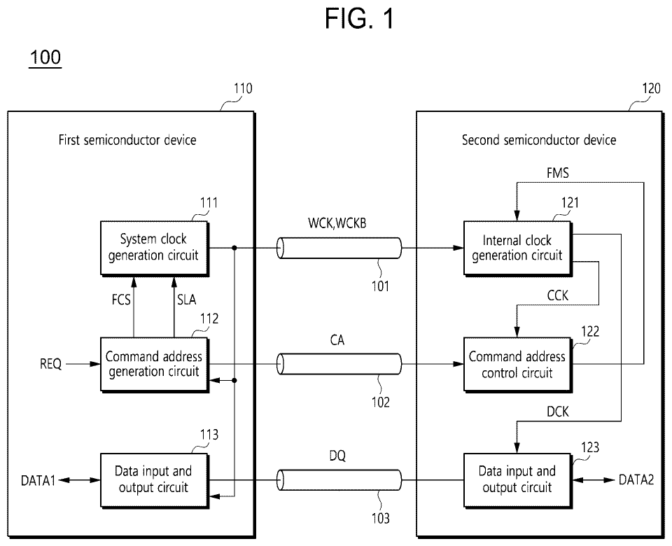

FIG. 1 is a block diagram illustrating a semiconductor system 100 according to an embodiment. Referring to FIG. 1, the semiconductor system 100 includes a first semiconductor device 110 and a second semiconductor device 120. The first semiconductor device 110 is a master device that provides various control signals that facilitate operation of the second semiconductor device 120. The second semiconductor device 120 is a slave device controlled by the first semiconductor device 110 and performs various operations. The first semiconductor device 110 may include various types of host devices. For example, the first semiconductor device 110 may include a central processing unit (CPU), a graphic processing unit (GPU), a multi-media processor (MMP), a digital signal processor, an application processor (AP), and a memory controller. The second semiconductor device 120 may be a memory device, for example. The memory device may include volatile memory and/or nonvolatile memory. The volatile memory may include static RAM (SRAM), dynamic RAM (DRAM), and synchronous DRAM (SDRAM). The nonvolatile memory may include read only memory (ROM), programmable ROM (PROM), electrically erasable and programmable ROM (EEPROM), electrically programmable ROM (EPROM), flash memory, phase change RAM (PRAM), magnetic RAM (MRAM), resistive RAM (RRAM), and ferroelectric RAM (FRAM). In an embodiment, the second semiconductor device may be graphic double data rate (GDDR) DRAM.

The second semiconductor device 120 is electrically coupled to the first semiconductor device 110 through a plurality of buses. The plurality of buses includes a signal transmission path, link, or channel that transmits a signal. The plurality of buses includes a clock bus 101, a command address bus 102, and a data bus 103. The clock bus 101 and the command address bus 102 may each be a unidirectional bus between the first semiconductor device 110 and the second semiconductor device 120. The data bus 103 may be a bidirectional bus. The second semiconductor device 120 is electrically coupled to the first semiconductor device 110 through the clock bus 101 and receives a system clock signal WCK through the clock bus 101. In an embodiment, the system clock signal WCK is transmitted along with a complementary system clock signal WCKB. The second semiconductor device 120 is electrically coupled to the first semiconductor device 110 through the command address bus 102 and receives a command address signal CA from the first semiconductor device 110 through the command address bus 102. The command address signal CA includes a plurality of bits. The first semiconductor device 110 transmits the command address signal CA based on the system clock signal WCK. The second semiconductor device 120 receives the command address signal CA based on the system clock signal WCK. The first semiconductor device 110 transmits the command address signal CA in synchronization with the system clock signal WCK. The second semiconductor device 120 synchronizes the command address signal CA with the system clock signal WCK. The second semiconductor device 120 is electrically coupled to the first semiconductor device 110 through the data bus 103 and receives data DQ from the first semiconductor device 110 and transmits the data DQ to the first semiconductor device 110 through the data bus 103. The first semiconductor device 110 transmits the data DQ to the second semiconductor device 120 and receives the data DQ transmitted by the second semiconductor device 120 in synchronization with the system clock signal WCK. The second semiconductor device 120 transmits the data DQ to the first semiconductor device 110 and receive the data DQ transmitted by the first semiconductor device 110 in synchronization with the system clock signal WCK.

The semiconductor system 100 operates according to various frequency bands. The first semiconductor device 110 communicates with the second semiconductor device 120 according to the system clock signal WCK having various frequencies. For example, the system clock signal WCK has a frequency within a high frequency band and a frequency within a low frequency band lower than the high frequency band. The semiconductor system 100 changes the frequency of the system clock signal WCK from one frequency band to the other frequency band by performing a clock frequency change. The semiconductor system 100 changes the frequency of the system clock signal WCK to another frequency within one frequency band by performing the clock frequency change. The first semiconductor device 110 provides the second semiconductor device 120 with the command address signal CA related to the clock frequency change before changing the frequency of the system clock signal WCK. The second semiconductor device 120 changes an internal circuit of the second semiconductor device 120 based on the command address signal CA related to the clock frequency change and receives the system clock signal WCK according to the frequency change.

The first semiconductor device 110 includes a system clock generation circuit 111, a command address generation circuit 112, and a data input, and output circuit 113. The system clock generation circuit 111 generates the system clock signal WCK and the complementary or inverted system clock signal WCKB. The system clock generation circuit 111 includes a clock generator that generates the system clock signal WCK. For example, the system clock generation circuit 111 may include an oscillator, a phase-locked loop circuit, or a delay-locked loop circuit. The system clock generation circuit 111 generates the system clock signal WCK at a frequency suitable for the first semiconductor device 110 to communicate with the second semiconductor device 120. The system clock generation circuit 111 transmits the system clock signal WCK to the second semiconductor device 120 through the clock bus 101. The system clock generation circuit 111 provides the system clock signal WCK to the command address generation circuit 112 and the data input and output circuit 113. The system clock generation circuit 111 generates the system clock signal WCK at various frequencies. The system clock generation circuit 111 receives a frequency change signal FCS. The frequency change signal FCS is provided by the command address generation circuit 112. The system clock generation circuit 111 changes the frequency of the system clock signal WCK based on the frequency change signal FCS. The frequency change signal FCS includes information related to or including a target frequency of the system clock signal WCK. The system clock generation circuit 111 generates the system clock signal WCK at a frequency corresponding to the information related to or including the target frequency.

When a user runs any application software and/or program, a request REQ is generated to operate the semiconductor system 100, and the request REQ is provided to the command address generation circuit 112. The command address generation circuit 112 generates the command address signal CA based on the request REQ. The command address generation circuit 112 generates the command address signal CA that instructs the second semiconductor device 120 to perform various operations based on the request REQ. The command address generation circuit 112 transmits the command address signal CA to the second semiconductor device 120 through the command address bus 102. The command address generation circuit 112 receives the system clock signal WCK and transmits the command address signal CA to the command address bus 102 in synchronization with the system clock signal WCK. The command address generation circuit 112 generates the command address signal CA including various types of information based on the request REQ. For example, the command address generation circuit 112 generates the command address signal CA related to the clock frequency change, the command address signal CA related to entry of a low power mode, and the command address signal CA related to termination of the low power mode. The command address signal CA related to the entry of the low power mode is a command address signal that instructs the second semiconductor device 120 to enter the low power mode. The command address signal CA related to the termination of the low power mode is a command address signal that instructs the second semiconductor device 120 to terminate the low power mode. The command address generation circuit 112 generates the command address signal CA related to an active operation, the command address signal CA related to a write operation, and the command address signal CA related to a read operation. The command address signal CA related to the active operation is a command address signal that activates the second semiconductor device 120 before the second semiconductor device 120 performs a write operation and a read operation. The command address signal CA related to the write operation is a command address signal indicative of an operation of the second semiconductor device 120 storing the data DQ transmitted by the first semiconductor device 110. The command address signal CA related to the read operation is a command address signal indicative of an operation of the second semiconductor device 110 outputting data stored in the second semiconductor device 120 to the first semiconductor device 110 as the data DQ.

The command address generation circuit 112 provides the system clock generation circuit 111 with information related to the target frequency, which is included in the command address signal CA, as the frequency change signal FCS, after transmitting the command address signal CA related to the clock frequency change to the second semiconductor device 120. The system clock generation circuit 111 changes the frequency of the system clock signal WCK based on the frequency change signal FCS. The frequency of the system clock signal WCK is changed after a predetermined time period or delay. The predetermined time period includes a time period sufficient for the second semiconductor device 120 to enter the low power mode. The predetermined time period is a time period from the time the command address generation circuit 112 transmits the command address signal CA related to the entry of the low power mode to the second semiconductor device 120 until the time when the second semiconductor device 120 enters the low power mode. In an embodiment, at least one of the command address generation circuit 112 and the system clock generation circuit 111 stores the frequency change signal FCS. The command address generation circuit 112 generates a low power mode notification signal SLA and provides the low power mode notification signal SLA to the system clock generation circuit 111. The command address generation circuit 112 enables the low power mode notification signal SLA when a sufficient time period elapses after transmitting the command address signal CA related to the entry of the low power mode. The command address generation circuit 112 disables the low power mode notification signal SLA when transmitting the command address signal CA related to the termination of the low power mode. In an embodiment, the system clock generation circuit 111 stores the frequency change signal FCS, stops the transmission of the system clock signal WCK when the low power mode notification signal SLA is enabled, and changes the frequency of the system clock signal WCK. In an embodiment, the command address generation circuit 112 stores the frequency change signal FCS and provides the frequency change signal FCS to the system clock generation circuit 111 when enabling the low power mode notification signal SLA. The system clock generation circuit 111 stops the transmission of the system clock signal WCK when the low power mode notification signal SLA is enabled and changes the frequency of the system clock signal WCK in response to receiving the frequency change signal FCS. The system clock generation circuit 111 transmits the system clock signal WCK to the second semiconductor device 120 through the clock bus 101 by resuming the transmission of the system clock signal WCK when the low power mode notification signal SLA is disabled.

The data input and output circuit 113 is electrically coupled to the second semiconductor device 120 through the data bus 103 and transmits the data DQ to the second semiconductor device 120 and receives the data DQ transmitted by the second semiconductor device 120 through the data bus 103. The data input and output circuit 113 generates the data DQ based on internal data DATA1 of the first semiconductor device 110 and transmits the data DQ to the second semiconductor device 120 through the data bus 103. The data input and output circuit 113 receives the data DQ transmitted by the second semiconductor device 120 through the data bus 103 and generates the internal data DATA1 based on the data DQ. The data input and output circuit 113 receives the system clock signal WCK and performs data input and output operations based on the system clock signal WCK. The data input and output circuit 113 transmits the internal data DATA1 of the first semiconductor device 110 as the data DQ in synchronization with the system clock signal WCK and generates the internal data DATA1 from the data DQ in synchronization with the system clock signal WCK.

The second semiconductor device 120 includes an internal clock generation circuit 121, a command address control circuit 122, and a data input and output circuit 123. The internal clock generation circuit 121 is electrically coupled to the clock bus 101 and receives the system clock signal WCK that is transmitted on the clock bus 101. When receiving the system clock signal WCK along with the complementary system clock signal WCKB, the internal clock generation circuit 121 receives the system clock signal WCK and the complementary system clock signal WCKB by differentially amplifying the system clock signal WCK and the complementary system clock signal WCKB. The internal clock generation circuit 121 generates a plurality of internal clock signals based on the system clock signal WCK. The internal clock generation circuit 121 generates a buffered clock signal by buffering the system clock signal WCK and generates the plurality of internal clock signals based on the buffered clock signal. The plurality of internal clock signals includes a command clock signal CCK and a data clock signal DCK. The internal clock generation circuit 121 provides the command clock signal CCK to the command address control circuit 122 and provides the data clock signal DCK to the data input and output circuit 123. The internal clock generation circuit 121 generates the command clock signal CCK and the data clock signal DCK by dividing the frequency of the buffered clock signal. In an embodiment, the command clock signal CCK has a lower frequency than the frequency of data clock signal DCK. The internal clock generation circuit 121 generates the command clock signal CCK by dividing the frequency of buffered clock signal according to a first division ratio. The internal clock generation circuit 121 generates the data clock signal DCK by dividing the frequency of the buffered clock signal according to a second division ratio. For example, the internal clock generation circuit 121 generates the command clock signal CCK by dividing the buffered clock signal frequency by four and generates the data clock signal DCK by dividing the buffered clock signal frequency into two. The internal clock generation circuit 121 receives a frequency mode signal FMS. The internal clock generation circuit 121 operates in one of a high frequency mode and a low frequency mode based on the frequency mode signal FMS and generates the command clock signal CCK and the data clock signal DCK from the system clock signal WCK. The high frequency mode is an operation mode in which the amplification gain can be increased for a clock signal having a relatively high frequency. The low frequency mode is an operation mode in which the amplification gain can be increased for a clock signal having a relatively low frequency. In an embodiment, the internal clock generation circuit 121 includes a delay-locked loop circuit and/or a phase-locked loop circuit capable of compensating for the time period during which the system clock signal WCK is delayed by internal circuits of the second semiconductor device 120. In an embodiment, the internal clock generation circuit 121 includes a command clock distribution network capable of distributing the command clock signal CCK to the command address control circuit 122. The internal clock generation circuit 121 includes a data clock distribution network capable of distributing the data clock signal DCK to the data input and output circuit 123.

The command address control circuit 122 is electrically coupled to the command address bus 102 and receives the command address signal CA that is transmitted by the first semiconductor device 110. The command address control circuit 122 receives the command clock signal CCK from the internal clock generation circuit 121 and synchronizes the command address signal CA with the command clock signal CCK. The command address control circuit 122 generates an internal command signal and an internal address signal by decoding the command address signal CA such that the second semiconductor device 120 performs various operations. The command address control circuit 122 generates the frequency mode signal FMS by receiving the command address signal CA related to the clock frequency change from the first semiconductor device 110. The command address control circuit 122 delays a time at which the frequency mode signal FMS is generated until the command address signal CA related to the entry of the low power mode is received even when the command address signal CA related to the clock frequency change is received. The command address control circuit 122 generates the frequency mode signal FMS based on information related to a target frequency of the system clock signal WCK, which is included in the command address signal CA related to the clock frequency change, after receiving the command address signal CA related to the entry of the low power mode.

The data input and output circuit 123 is electrically coupled to the first semiconductor device 110 through the data bus 103 and transmits the data DQ to the first semiconductor device 110 or receives the data DQ transmitted by the first semiconductor device 110 through the data bus 103. The data input and output circuit 123 generates the data DQ based on internal data DATA2 of the second semiconductor device 120 and transmits the data DQ to the first semiconductor device 110 through the data bus 103. The data input and output circuit 123 receives the data DQ transmitted by the first semiconductor device 110 through the data bus 103 and generates the internal data DATA2 based on the data DQ. The data input and output circuit 123 receive the data clock signal DCK generated by the internal clock generation circuit 121. The data input and output circuit 123 performs input and output operations on the data DQ based on the data clock signal DCK. The data input and output circuit 123 transmits the data DQ to the first semiconductor device 110 in synchronization with the data clock signal DCK and receives the data DQ transmitted by the first semiconductor device 110 in synchronization with the data clock signal DCK.

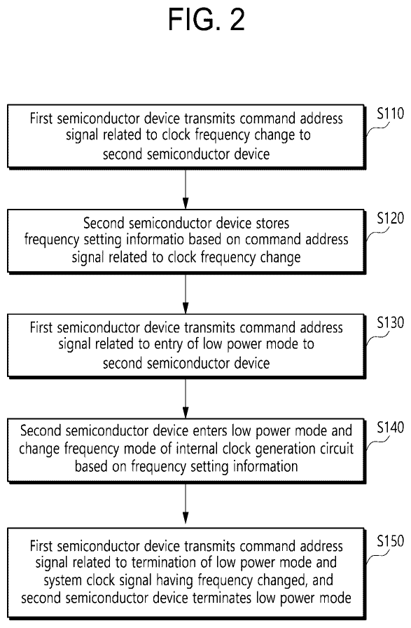

FIG. 2 is a flowchart illustrating operation of the semiconductor system 100 according to an embodiment. A clock frequency change operation of the semiconductor system 100 according to an embodiment is described with reference to FIG. 1 and FIG. 2. The first semiconductor device 110 transmits S110 the command address signal CA related to a clock frequency change to the second semiconductor device 120. The first semiconductor device 110 transmits the command address signal CA related to the clock frequency change to the second semiconductor device 120 at a point in time when the second semiconductor device 120 operates in an active mode or an idle mode. The command address generation circuit 112 generates the command address signal CA related to the clock frequency change and transmits the command address signal CA related to the clock frequency change to the second semiconductor device 120. In an embodiment, the command address generation circuit 112 stores the frequency change signal FCS relating to information related to a target frequency that is included in the command address signal CA related to the clock frequency change. In an embodiment, the command address generation circuit 112 provides the frequency change signal FCS to the system clock generation circuit 111. The system clock generation circuit 111 stores the frequency change signal FCS.

The second semiconductor device 120 receives the command address signal CA related to the clock frequency change, which is transmitted by the first semiconductor device 110, and stores S120 frequency setting information based on the command address signal CA related to the clock frequency change. The frequency setting information corresponds to the information related to the target frequency of the system clock signal WCK. The command address control circuit 122 stores the frequency setting information based on the command address signal CA related to the clock frequency change and delays the point in time at which the frequency mode signal FMS is generated.

The first semiconductor device 110 transmits S130 the command address signal CA related to the entry of the low power mode to the second semiconductor device 120. The command address control circuit 122 receives the command address signal CA related to the entry of the low power mode and controls entry of the second semiconductor device 120 into the low power mode.

The second semiconductor device 120 enters S140 the low power mode based on the command address signal CA related to the entry of the low power mode. The low power mode is an operation mode in which the second semiconductor device 120 may consume less power than is consumed in other operation modes and may include at least one of a power-down mode, a deep power-down mode, a self-refresh sleep mode, and a sleep mode. During the low power mode, the second semiconductor device 120 does not use the system clock signal WCK. After entering the low power mode, the second semiconductor device 120 changes the frequency mode of the internal clock generation circuit 121 based on the frequency setting information. When the target frequency of the system clock signal WCK included in the frequency setting information is included in a high frequency band, the command address control circuit 122 enables the frequency mode signal FMS, and the internal clock generation circuit 121 operates in the high frequency mode. When the target frequency of the system clock signal WCK included in the frequency setting information is included in a low frequency band, the command address control circuit 122 disables the frequency mode signal FMS, and the internal clock generation circuit 121 operates in the low frequency mode. After transmitting the command address signal CA related to the entry of the low power mode to the second semiconductor device 120, the command address generation circuit 112 provides the low power mode notification signal SLA to the system clock generation circuit 111 after a predetermined time period. When the low power mode notification signal SLA is enabled, the system clock generation circuit 111 stops the transmission of the system clock signal WCK to the second semiconductor device 120. The system clock generation circuit 111 generates the system clock signal WCK at a frequency corresponding to the target frequency based on the frequency change signal FCS.

The first semiconductor device 110 transmits S150 the command address signal CA related to the termination of the low power mode to the second semiconductor device 120. The first semiconductor device 110 transmits the system clock signal WCK at a changed frequency to the second semiconductor device 120 based on the frequency change signal FCS. After transmitting the command address signal CA related to the termination of the low power mode to the second semiconductor device 120, the command address generation circuit 112 disables the low power mode notification signal SLA. When the low power mode notification signal SLA is disabled, the system clock generation circuit 111 transmits the system clock signal WCK to the second semiconductor device 120. The second semiconductor device 120 terminates the low power mode based on the command address signal CA related to the termination of the low power mode. When the low power mode is the self-refresh sleep mode, the second semiconductor device 120 terminates the low power mode and enters the self-refresh operation mode. When the low power mode is the sleep mode, the second semiconductor device 120 terminates the low power mode and enters the idle mode. Although the second semiconductor device 120 receives the command address signal CA related to the clock frequency change from the first semiconductor device 110, the second semiconductor device 120 delays the point in time at which the frequency mode of the internal clock generation circuit 121 is changed after entering the low power mode or changes the frequency mode of the internal clock generation circuit 121 after entering the low power mode. The second semiconductor device 120 can prevent the frequency mode of the internal clock generation circuit 121 from changing before receiving the system clock signal WCK at a changed frequency because the second semiconductor device 120 does not use the system clock signal WCK during the low power mode. Accordingly, malfunction of the second semiconductor device 120 and the semiconductor system 100 may be avoided or eliminated.

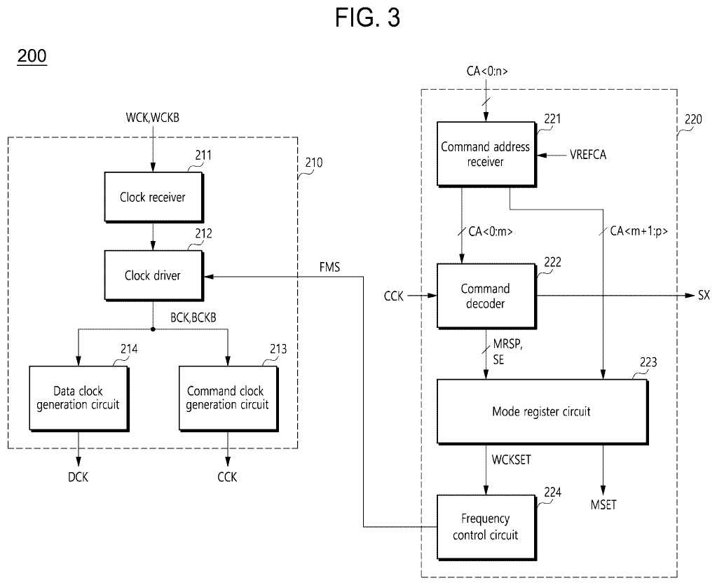

FIG. 3 is a diagram illustrating a semiconductor device 200 according to an embodiment. The second semiconductor device 120 illustrated in FIG. 1 includes components of the semiconductor device 200. The semiconductor device 200 includes an internal clock generation circuit 210 and a command address control circuit 220. The internal clock generation circuit 210 corresponds to the internal clock generation circuit 121 of FIG. 1. The command address control circuit 220 corresponds to the command address control circuit 122 of FIG. 1. The internal clock generation circuit 210 is electrically coupled to the clock bus 101 illustrated in FIG. 1 and receives the system clock signal WCK transmitted on the clock bus 101. The internal clock generation circuit 210 receives the complementary system clock signal WCKB along with the system clock signal WCK. The internal clock generation circuit 210 operates in one of the high frequency mode and the low frequency mode. The internal clock generation circuit 210 generates the command clock signal CCK from the system clock signal WCK by operating in one of the high frequency mode and the low frequency mode. The internal clock generation circuit 210 operates in a frequency mode suitable for the frequency of the system clock signal WCK. When the system clock signal WCK is at a frequency included in a high frequency band, the internal clock generation circuit 210 generates the command clock signal CCK from the system clock signal WCK by operating in the high frequency mode. When operating in the high frequency mode, the internal clock generation circuit 210 has a gain and/or current driving power suitable for driving and/or buffering a clock signal at a high frequency. When the system clock signal WCK is at a frequency included in a low frequency band, the internal clock generation circuit 210 generates the command clock signal CCK from the system clock signal WCK by operating in the low frequency mode. When operating in the low frequency mode, the internal clock generation circuit 210 has a gain and/or current driving power suitable for driving and/or buffering a clock signal at a high frequency. The internal clock generation circuit 210 receives the frequency mode signal FMS. The internal clock generation circuit 210 operates in one of the high frequency mode and the low frequency mode based on the frequency mode signal FMS. For example, when the frequency mode signal FMS is enabled, the internal clock generation circuit 210 operates in the high frequency mode. When the frequency mode signal FMS is disabled, the internal clock generation circuit 210 operates in the low frequency mode. The internal clock generation circuit 210 generates the data clock signal DCK from the system clock signal WCK. The internal clock generation circuit 210 generates the command clock signal CCK and the data clock signal DCK by dividing a frequency of the system clock signal WCK. A ratio according to which the internal clock generation circuit 210 divides the frequency of the system clock signal WCK to generate the command clock signal CCK may be different from a ratio according to which the internal clock generation circuit 210 divides the frequency of the system clock signal WCK to generate the data clock signal DCK.

The command address control circuit 220 is electrically coupled to the command address bus 102 illustrated in FIG. 1 and receives the command address signal CA<0:n> transmitted on the command address bus 102. The command address signal CA<0:n> include (n+1) bits, where n is an integer equal to or greater than 2. The command address control circuit 220 changes the frequency mode of the internal clock generation circuit 210 based on the command address signal CA<0:n>. The command address control circuit 220 generates the frequency mode signal FMS based on the command address signal CA<0:n> such that the frequency mode of the internal clock generation circuit 210 is changed. The command address control circuit 220 provides the frequency mode signal FMS to the internal clock generation circuit 210. The command address signal CA<0:n> is transmitted during a plurality of cycles of the system clock signal WCK. The plurality of cycles includes, for example, 2 cycles, 4 cycles, 8 cycles, and so forth. The command address signals CA<0:n> transmitted during the plurality of cycles forms one command address signal set. For example, one command address signal set includes p bits, where p is 2n, 4n, or 8n. When receiving the command address signal CA<0:p> related to the clock frequency change, the command address control circuit 220 generates the frequency mode signal FMS to change the frequency mode of the internal clock generation circuit 210. Although the command address control circuit 220 receives the command address signal CA<0:p> related to a clock frequency change, the command address control circuit 220 does not immediately generate the frequency mode signal FMS and does not change the frequency mode of the internal clock generation circuit 210. The command address control circuit 220 delays the point in time at which the frequency mode of the internal clock generation circuit 210 is changed until the semiconductor device 200 enters the low power mode. After the semiconductor device 200 enters the low power mode, the command address control circuit 220 generates the frequency mode signal FMS and provides the frequency mode signal FMS to the internal clock generation circuit 210.

The internal clock generation circuit 210 includes a clock receiver 211, a clock driver 212, a command clock generation circuit 213, and a data clock generation circuit 214. The clock receiver 211 is electrically coupled to the clock bus 101 and receives the system clock signal WCK that is transmitted on the clock bus 101. The clock receiver 211 receives the system clock signal WCK and the complementary system clock signal WCKB that are generated by differentially amplifying the system clock signal WCK and the complementary system clock signal WCKB. The clock receiver 211 outputs the system clock signal WCK and the complementary system clock signal WCKB to the clock driver 212.

The clock driver 212 receives the system clock signal WCK and the complementary system clock signal WCKB that are received through the clock receiver 211. The clock driver 212 generates the buffered clock signal BCK and the buffered complementary clock signal BCKB by buffering the system clock signal WCK and the complementary system clock signal WCKB. The clock driver 212 may be a driver circuit that operates in a wide frequency band. The clock driver 212 receives the frequency mode signal FMS and operates in one of the high frequency mode and the low frequency mode based on the frequency mode signal FMS. The clock driver 212 operates in the high frequency mode when the frequency mode signal FMS is enabled and buffers the system clock signal WCK and the complementary system clock signal WCKB. The clock driver 212 operates in the low frequency mode when the frequency mode signal FMS is disabled and buffers the system clock signal WCK and the complementary system clock signal WCKB. When the clock driver 212 operates in the high frequency mode, the state of the clock driver 212 is a state in which the clock driver 212 is suitable for buffering a clock signal at a high frequency. For example, when operating in the high frequency mode, the clock driver 212 has an increased or equalized AC (alternating current) gain. When the clock driver 212 operates in the low frequency mode, the state of the clock driver 212 is a state in which the clock driver 212 is suitable for buffering a clock signal having a low frequency. For example, when operating in the low frequency mode, the clock driver 212 has an increased DC gain. The clock driver 212 provides the buffered clock signal BCK and the buffered complementary clock signal BCKB to the command clock generation circuit 213 and the data clock generation circuit 214.

The command clock generation circuit 213 receives the buffered clock signal BCK and the buffered complementary clock signal BCKB and generates the command clock signal CCK by dividing the frequency of the buffered clock signal BCK and the buffered complementary clock signal BCKB. The command clock generation circuit 213 generates the command clock signal CCK by dividing the frequency of the buffered clock signal BCK and the buffered complementary clock signal BCKB at a first division ratio. For example, the command clock generation circuit 213 generates the command clock signal CCK by dividing the frequency of each of the buffered clock signal BCK and the buffered complementary clock signal BCKB into two. The frequency of the command clock signal CCK may be ½ of the frequency of the buffered clock signal BCK. The cycle of the command clock signal CCK may be two times or twice the cycle or frequency of the buffered clock signal BCK. The command clock generation circuit 213 provides the command clock signal CCK to the command address control circuit 220.

The data clock generation circuit 214 receives the buffered clock signal BCK and the buffered complementary clock signal BCKB and generates the data clock signal DCK by dividing the frequency of each of the buffered clock signal BCK and the buffered complementary clock signal BCKB. The data clock generation circuit 214 generates the data clock signal DCK by dividing the frequency of each of the buffered clock signal BCK and the buffered complementary clock signal BCKB according to a second division ratio. For example, the data clock generation circuit 214 may generate the data clock signal DCK by dividing the frequency of each of the buffered clock signal BCK and the buffered complementary clock signal BCKB by four. The frequency of the data clock signal DCK may be ¼ of the frequency of the buffered clock signal BCK. The cycle or frequency of the data clock signal DCK may be four times the cycle or frequency of the buffered clock signal BCK. The data clock generation circuit 214 provides the data clock signal DCK to the data input and output circuit 123 illustrated in FIG. 1.

The command address control circuit 220 includes a command address receiver 221, a command decoder 222, a mode register circuit 223, and a frequency control circuit 224. The command address receiver 221 is electrically coupled to the command address bus 102 illustrated in FIG. 1 and receives the command address signal CA<0:n> transmitted on the command address bus 102. The command address receiver 221 receives the command address signal CA<0:n> and compares each of the bits of the command address signal CA<0:n> with a reference voltage VREFCA. The command address receiver 221 provides the command decoder 222 and the mode register circuit 223 with the command address signal CA<0:p> received during a plurality of cycles. Some, m+1, of the bits of the command address signal CA<0:p> are provided to the command decoder 222 and the rest of the bits of the command address signal CA<0:p> are provided to the mode register circuit 223. For example, the first to (m+1) bits CA<0:m> of the command address signal are provided to the command decoder 222, and the (m+2) to (p+1) bits CA<m+1:p> of the command address signal are provided to the mode register circuit 223. In this example, m may be an integer between 1 and p-1.

The command decoder 222 receives the command address signal CA<0:m> received through the command address receiver 221. The command decoder 222 receives the command clock signal CCK and synchronize the command address signal CA<0:m> with the command clock signal CCK. For example, the command decoder 222 latches the command address signal CA<0:m> in synchronization with the command clock signal CCK. The command decoder 222 generates various internal signals based on the command address signal CA<0:m>. The command decoder 222 generates the various internal signals by decoding the first to (m+1) bits CA<0:m> of the command address signal. The various internal signals include at least a mode register setting signal MRSP, a low power mode entry signal SLE, and a low power mode termination signal SLX. When receiving the command address signal CA<0:m> related to the clock frequency change and setting the mode register, the command decoder 222 generates the mode register setting signal MRSP by decoding the first to (m+1) bits CA<0:m> of the command address signal. When receiving the command address signal CA<0:m> related to the entry of the low power mode, the command decoder 222 may generate the low power mode entry signal SE by decoding the first to (m+1) bits CA<0:m> of the command address signal. In response to receiving the command address signal CA<0:m> related to the termination of the low power mode, the command decoder 222 generates the low power mode termination signal SLX by decoding the first to (m+1) bits CA<0:m> of the command address signal.

The mode register circuit 223 receives the command address signal CA<m+1:p> and may receive the mode register setting signal MRSP and the low power mode entry signal SE from the command decoder 222. The mode register circuit 223 receives the (m+2) to (p+1) bits CA<m+1:p> of the command address signal. The (m+2) to (p+1) bits CA<m+1:p> of the command address signal includes address information and mode register setting information for the mode register circuit 223. The mode register circuit 223 stores the mode register setting information at a location corresponding to the address information. When the mode register setting signal MRSP is asserted, the mode register circuit 223 stores some of the (m+2) to (p+1) bits CA<m+1:p> of the command address signal as the mode register setting information. When the mode register setting signal MRSP is generated based on the command address signal CA<0:m> related to the clock frequency change, the mode register circuit 223 stores some of the (m+2) to (p+1) bits CA<m+1:p> of the command address signal as frequency setting information WCKSET. When the mode register setting signal MRSP is generated based on the command address signal CA<0:m> related to another mode register setting other than the clock frequency change, the mode register circuit 223 stores some of the (m+2) to (p+1) bits CA<m+1:p> of the command address signal as another mode register setting information MSET. The mode register circuit 223 outputs the frequency setting information WCKSET and the another mode register setting information MSET. The mode register circuit 223 stores the another mode register setting information MSET and outputs the another mode register setting information MSET without any delay. The mode register circuit 223 may temporarily store the frequency setting information WCKSET and delay a time at which the frequency setting information WCKSET is output. The mode register circuit 223 does not output the frequency setting information WCKSET until the low power mode signal SE is asserted. The mode register circuit 223 outputs the frequency setting information WCKSET when the low power mode signal SE is asserted.

The frequency control circuit 224 receives the frequency setting information WCKSET from the mode register circuit 223. The frequency control circuit 224 generates the frequency mode signal FMS based on the frequency setting information WCKSET. The frequency control circuit 224 determines whether the target frequency of the system clock signal WCK is included in a high frequency band or a low frequency band based on the frequency setting information WCKSET. When the target frequency of the system clock signal WCK is included in the high frequency band, the frequency control circuit 224 enables the frequency mode signal FMS. When the target frequency of the system clock signal WCK is included in the low frequency band, the frequency control circuit 224 disables the frequency mode signal FMS.

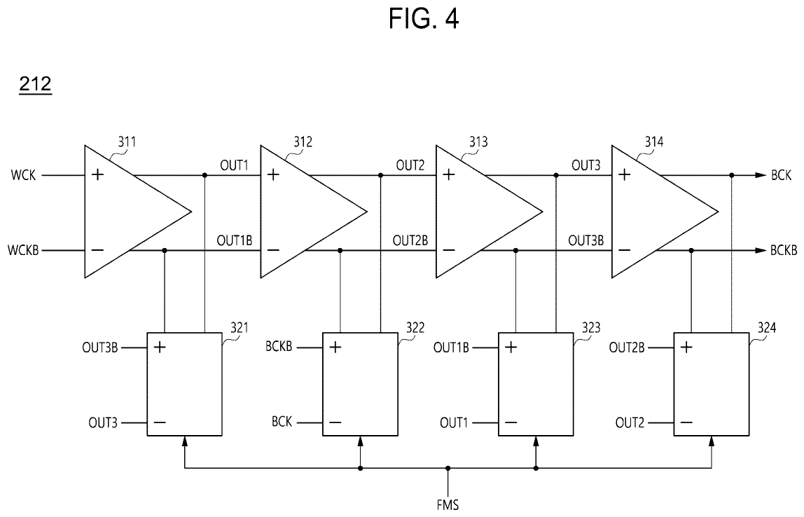

FIG. 4 is a diagram illustrating an embodiment of the clock driver 212, for example, as illustrated in FIG. 3. Referring to FIG. 4, the clock driver 212 includes a first amplification circuit 311, a second amplification circuit 312, a third amplification circuit 313, a fourth amplification circuit 314, a first equalization circuit 321, a second equalization circuit 322, a third equalization circuit 323, and a fourth equalization circuit 324. The first amplification circuit 311 receives the system clock signal WCK and the complementary system clock signal WCKB and generates a first output signal OUT1 and a first complementary output signal OUT1B by differentially amplifying the system clock signal WCK and the complementary system clock signal WCKB. The second amplification circuit 312 receives the first output signal OUT1 and the first complementary output signal OUT1B and generates a second output signal OUT2 and a second complementary output signal OUT2B by differentially amplifying the first output signal OUT1 and the first complementary output signal OUT1B. The third amplification circuit 313 receives the second output signal OUT2 and the second complementary output signal OUT2B and generates a third output signal OUT3 and a third complementary output signal OUT3B by differentially amplifying the second output signal OUT2 and the second complementary output signal OUT2B. The fourth amplification circuit 314 receives the third output signal OUT3 and the third complementary output signal OUT3B and generates the buffered clock signal BCK and the buffered complementary clock signal BCKB by differentially amplifying the third output signal OUT3 and the third complementary output signal OUT3B. The amplification circuits 311, 312, 313, and 314 each include a differential amplification circuit. The differential amplification circuit may include a current mode logic (CML) driver.

The first equalization circuit 321 receives the third output signal OUT3 and the third complementary output signal OUT3B, and is electrically coupled to the output nodes of the first amplification circuit 311. The first equalization circuit 321 equalizes the voltage levels of the first output signal OUT1 and the first complementary output signal OUT1B based on the third output signal OUT3 and the third complementary output signal OUT3B. For example, the first equalization circuit 321 changes the voltage level of the first output signal OUT1 based on the third complementary output signal OUT3B and changes the voltage level of the first complementary output signal OUT1B based on the third output signal OUT3. The second equalization circuit 322 receives the buffered clock signal BCK and the buffered complementary clock signal BCKB and is electrically coupled to the output nodes of the second amplification circuit 312. The second equalization circuit 322 equalizes the voltage levels of the second output signal OUT2 and the second complementary output signal OUT2B based on the buffered clock signal BCK and the buffered complementary clock signal BCKB. For example, the second equalization circuit 322 changes the voltage level of the second output signal OUT2 based on the buffered complementary clock signal BCKB and changes the voltage level of the second complementary output signal OUT2B based on the buffered clock signal BCK. The third equalization circuit 323 receives the first output signal OUT1 and the first complementary output signal OUT1B and is electrically coupled to the output nodes of the third amplification circuit 313. The third equalization circuit 323 equalizes the voltage levels of the third output signal OUT3 and the third complementary output signal OUT3B based on the first output signal OUT1 and the first complementary output signal OUT1B. For example, the third equalization circuit 323 changes the voltage level of the third output signal OUT3 based on the first complementary output signal OUT1B and changes the voltage level of the third complementary output signal OUT3B based on the first output signal OUT1. The fourth equalization circuit 324 receives the second output signal OUT2 and the second complementary output signal OUT2B and is electrically coupled to the output nodes of the fourth amplification circuit 314. The fourth equalization circuit 324 equalizes the voltage levels of the buffered clock signal BCK and the buffered complementary clock signal BCKB based on the second output signal OUT2 and the second complementary output signal OUT2B. For example, the fourth equalization circuit 324 changes the voltage level of the buffered clock signal BCK based on the second complementary output signal OUT2B and changes the voltage level of the buffered complementary clock signal BCKB based on the second output signal OUT2.

The equalization circuits 321, 322, 323, and 324 each receive the frequency mode signal FMS, and may each be selectively activated based on the frequency mode signal FMS. When the frequency mode signal FMS is enabled, the equalization circuits 321, 322, 323, and 324 are each activated to perform an equalization operation. When each of the equalization circuits 321, 322, 323, and 324 performs the equalization operation, an AC gain of the clock driver 212 is increased, and the clock driver 212 becomes suitable to propagate a clock signal at a relatively high frequency. When the frequency mode signal FMS is disabled, each of the equalization circuits 321, 322, 323, and 324 is deactivated and does not perform an equalization operation. When each of the equalization circuits 321, 322, 323, and 324 does not perform an equalization operation, a DC gain of the clock driver 212 is increased, and the clock driver 212 becomes suitable for propagating a clock signal at a relatively low frequency. The clock driver 212 is illustrated including four stages, but the clock driver 212 may include stages fewer than or greater than four stages.

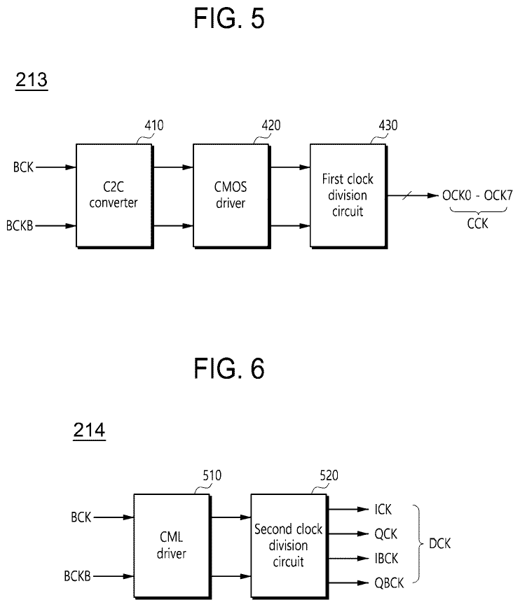

FIG. 5 is a diagram illustrating an embodiment of the command clock generation circuit 213, for example, as illustrated in FIG. 3. Referring to FIG. 5, the command clock generation circuit 213 includes a chip-to-chip (C2C) converter 410, a complementary metal oxide semiconductor (CMOS) driver 420, and a first clock division circuit 430. For example, the C2C converter 410 is a CML to CMOS converter that converts a signal having a CML level into a signal having a CMOS level. The C2C converter 410 converts the buffered clock signal BCK and the buffered complementary clock signal BCKB that swing at the CML level into signals that swing at the CMOS level. The CMOS driver 420 receives the output signal of the C2C converter 410 and buffers the output signal of the C2C converter 410. The first clock division circuit 430 receives the output signal of the CMOS driver 420 and generates the command clock signal CCK by dividing the frequency of the output signal of the CMOS driver 420. The first clock division circuit 430 generates the command clock signal CCK by dividing the frequency of the output signal of the CMOS driver 420 by four. The first clock division circuit 430 generates eight division clock signals OCK1 to OCK8 having different phases by dividing the frequency of the output signal of the CMOS driver 420 by four. The eight division clock signals OCK1 to OCK8 may sequentially have phase differences at 45 degrees. The first clock division circuit 430 outputs some or all of the eight division clock signals OCK1 to OCK8 as the command clock signal CCK.

FIG. 6 is a diagram illustrating an embodiment of the data clock generation circuit 214, for example, as illustrated in FIG. 3. Referring to FIG. 6, the data clock generation circuit 214 includes a CML driver 510 and a second clock division circuit 520. The CML driver 510 receives the buffered clock signal BCK and the buffered complementary clock signal BCKB and buffer the buffered clock signal BCK and the buffered complementary clock signal BCKB. The CML driver 510 generates signals that swing at the CML level similarly to the buffered clock signal BCK and the buffered complementary clock signal BCKB. The second clock division circuit 520 receives the output signal of the CML driver 510 and generates the data clock signal DCK by dividing the output signal of the CML driver 510. The second clock division circuit 520 generates the data clock signal DCK by dividing the frequency of the output signal of the CML driver 510 by two. The second clock division circuit 520 generates four division clock signals ICK, QCK, IBCK, and QBCK having different phases by dividing the frequency of the output signal of the CML driver 510 by two. The four division clock signals ICK, QCK, IBCK, and QBCK sequentially have phase differences of 90 degrees. The second clock division circuit 520 outputs some or all of the four division clock signals ICK, QCK, IBCK, and QBCK as the data clock signal DCK.

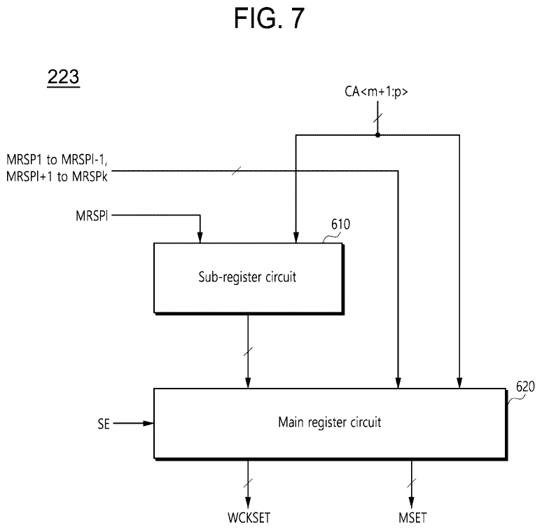

FIG. 7 is a diagram illustrating an embodiment of the mode register circuit 223, for example, as illustrated in FIG. 3. Referring to FIG. 7, the mode register circuit 223 includes a sub-register circuit 610 and a main register circuit 620. The sub-register circuit 610 receives the mode register setting signal MRSP and the command address signal CA<m+1:p> illustrated in FIG. 3. The mode register setting signal MRSP includes a plurality of setting signals. The sub-register circuit 610 receives a specific setting signal, among the plurality of setting signals. The specific setting signal is the mode register setting signal MRSP generated by the command decoder 222 illustrated in FIG. 3 when the command address signal CA<0:p> related to the clock frequency change is received. For example, the quantity of the plurality of setting signals MRSP1 to MRSPk is k. The specific setting signal is an I-th setting signal MRSPI. In this example, k is an integer equal to or greater than 3, and I is an integer between 1 and k. When receiving the command address signal CA<0:p> related to the clock frequency change, the command decoder 222 generates the I-th setting signal MRSPI. In response to receiving the command address signal CA<0:p> related to the setting of another mode register other than the clock frequency change, the command decoder 222 generates at least one different signal of setting signals MRSP1 to MRSPI−1 and MRSPI+1 to MRSPk except not the I-th setting signal MRSPI. The sub-register circuit 610 stores the command address signal CA<m+1:p> based on the I-th setting signal MRSPI. The sub-register circuit 610 outputs the command address signal CA<m+1:p> to the main register circuit 620. The sub-register circuit 610 temporarily stores the command address signal CA<m+1:p> such that the frequency setting information WCKSET stored in the main register circuit 620 is not immediately changed.

The main register circuit 620 receives the command address signal CA<m+1:p> stored in the sub-register circuit 610. The main register circuit 620 receives the plurality of setting signals MRSP1 to MRSPI−1 and MRSPI+1 to MRSPk except for the I-th setting signal MRSPI and receives the command address signal CA<m+1:p> received through the command address receiver 221. The main register circuit 620 receives the low power mode entry signal SE generated by the command decoder 222. The main register circuit 620 does not change the frequency setting information WCKSET stored in the main register circuit 620 although the main register circuit 620 receives the command address signal CA<m+1:p> stored in the sub-register circuit 610 from the sub-register circuit 610. In response to receiving the low power mode entry signal SE, the main register circuit 620 updates the frequency setting information WCKSET based on the command address signal CA<m+1:p> stored in the sub-register circuit 610. The main register circuit 620 outputs the frequency setting information WCKSET to the frequency control circuit 224 of FIG. 3. In response to receiving the plurality of setting signals MRSP1 to MRSPI−1 and MRSPI+1 to MRSPk, the main register circuit 620 updates the another mode register setting information MSET other than the frequency setting information WCKSET based on the command address signal CA<m+1:p> received through the command address receiver 221. The main register circuit 620 outputs the another mode register setting information MSET to a different internal circuit of the semiconductor device 200.

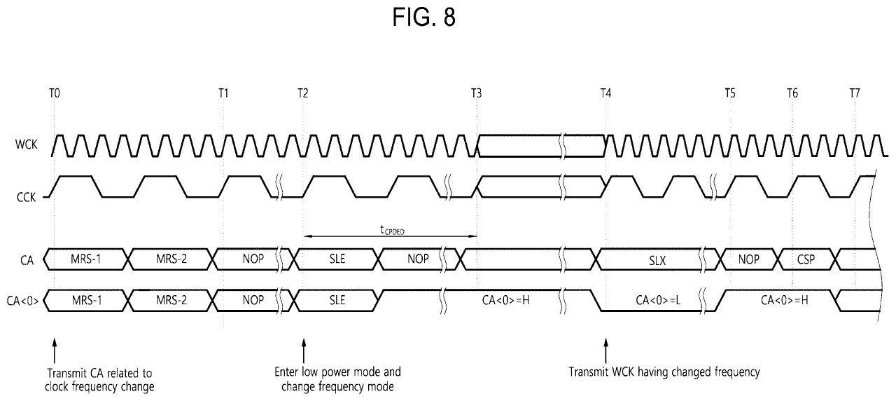

FIG. 8 is a timing diagram illustrating operation of the semiconductor system 100 according to an embodiment. The operation of the semiconductor system 100 according to an embodiment is described with reference to FIG. 1 to FIG. 8. Prior to time T0, the second semiconductor device 120 operates in the active mode or the idle mode. The first semiconductor device 110 provides the second semiconductor device 120 with the system clock signal WCK at a first frequency. For the first semiconductor device 110 to change the frequency of the system clock signal WCK from the first frequency to a second frequency at time T0, the first semiconductor device 110 provides the second semiconductor device 120 with the command address signals CA, MRS-1, MRS-2 related to the clock frequency change. The command address signals MRS-1, MRS-2 related to the clock frequency change are provided from the first semiconductor device 110 to the second semiconductor device 120 during eight cycles of the system clock signal WCK or two cycles of the command clock signal CCK. For example, as illustrated in FIG. 3, the command address signal CA<0:n> including n bits is transmitted on the command address bus 101 during one cycle of the system clock signal WCK. The command address signals MRS-1, MRS-2 related to the clock frequency change include a total of 8n bits. The second semiconductor device 120 does not immediately perform a clock frequency change operation although the second semiconductor device receives the command address signals MRS-1, MRS-2 related to the clock frequency change. The command decoder 222 generates the I-th setting signal MRSPI based on the command address signal CA<0:m>. The sub-register circuit 610 temporarily stores the command address signal CA<m+1:p>. The main register circuit 620 does not immediately update the frequency setting information WCKSET based on the command address signal CA<m+1:p>.

Between time T1 and time T2, the semiconductor system 100 does not perform any operation (NOP), and the first semiconductor device 110 does not provide any command address signal CA to the second semiconductor device 120. The semiconductor system 100 does not perform any operation between time T1 and time T2 in this example, although the semiconductor system 100 is modified to perform an operation between time T1 and time T2. At time T2, the first semiconductor device 110 transmits the command address signal CA, as low power mode notification signal SLE related to the entry of the low power mode, to the second semiconductor device 120. The command address signal SLE related to the entry of the low power mode is provided from the first semiconductor device 110 to the second semiconductor device 120 during four cycles of the system clock signal WCK or one cycle of the command clock signal CCK. For example, the address signal SLE related to the entry of the low power mode includes a total of 4n bits. The second semiconductor device 120 enters the low power mode based on the command address signal SLE. After entering the low power mode, the second semiconductor device 120 performs a clock frequency change operation. The command decoder 222 generates the low power mode entry signal SLE based on the command address signal CA<0:m>. When receiving the low power mode entry signal SLE, the main register circuit 620 updates the frequency setting information WCKSET based on the command address signal CA<m+1:p> stored in the sub-register circuit 610. Accordingly, a frequency included in the frequency setting information WCKSET stored in the main register circuit 620 is changed from the first frequency to the second frequency. The frequency control circuit 224 enables or disables the frequency mode signal FMS based on the frequency setting information WCKSET. When the first frequency is included in a low frequency band and the second frequency is included in a high frequency band, the frequency control circuit 224 enables the frequency mode signal FMS. The state of the clock driver 212 is a state in which the clock driver 212 is suitable for buffering the system clock signal WCK having a high frequency based on the frequency mode signal FMS. The second semiconductor device 120 enters the low power mode during the time period between time T2 and time T3. The time period tCPDED between time T2 and time T3 corresponds to a predetermined time period during which the second semiconductor device 120 enters the low power mode in response to receiving the command address signal SLE related to the entry of the low power mode. After transmitting the command address signal SLA related to the entry of the low power mode, the first semiconductor device 110 no longer provides the command address signal to the second semiconductor device 120 (NOP) and does not provide the system clock signal WCK to the second semiconductor device 120 after time T3. The low power mode continues between time T3 and time T4. After transmitting the command address signal SLE related to entry of the low power mode, the first semiconductor device 110 maintains a specific bit of the command address signal CA, for example, a first bit CA<0>, at a logic high level H.

At time T4, the first semiconductor device 110 transmits the command address signal CA, as power mode termination signal SLX, related to the termination of the low power mode to the second semiconductor device 120. The first semiconductor device 110 transmits the system clock signal WCK at the second frequency to the second semiconductor device 120. The second semiconductor device 120 generates the command clock signal CCK and the data clock signal DCK normally from the system clock signal WCK because the clock driver 212 operates in the high frequency mode before the first semiconductor device 110 transmits the system clock signal WCK at the second frequency. In the example of FIG. 8, the timing at which the first semiconductor device 110 provides the system clock signal WCK and the time at which the first semiconductor device 110 provides the command address signal SLX related to the termination of the low power mode are substantially the same. The time at which the first semiconductor device 110 provides the system clock signal WCK may be before the time at which the first semiconductor device 110 provides the command address signal SLX or after the time at which the first semiconductor device 110 provides the command address signal SLX. The command address signal SLX is not synchronized with the system clock signal WCK and maintains a transmission state for a time period. In an embodiment, when providing the command address signal SLX related to the termination of the low power mode, the first semiconductor device 110 maintains the first bit CA<0> of the command address signal at a logic low level L. The second semiconductor device 120 terminates the low power mode based on the command address signal CA. The command decoder 222 generates the low power mode termination signal SLX based on the command address signal CA<0:m>. The second semiconductor device 120 enters the self-refresh mode or the idle mode. At time T5, when the transmission of the command address signal CA related to the termination of the low power mode is completed, the first semiconductor device 110 changes the first bit CA<0> of the command address signal to a logic high level H.

The first semiconductor device 110 does not provide the command address signal CA (NOP) between time T5 and time T6. At time T6, the first semiconductor device 110 provides the second semiconductor device 120 with the command address signal CSP related to command start timing. The command address signal CSP related to command start timing is provided from the first semiconductor device 110 to the second semiconductor device 120 during four cycles of the system clock signal WCK or one cycle of the command clock signal CCK. For example, the address signal CSP related to the command start timing includes a total of 4n bits. After the command address signal CA related to the termination of the low power mode is transmitted, the first bit of the command address signal is changed to a logic high level H between time T5 and time T7. After time T7, the first semiconductor device 110 transmits the command address signal CA indicative of various operations to the second semiconductor device 120. The command address signal CA is transmitted in synchronization with the system clock signal WCK at the second frequency.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the above descriptions. All changes within the meaning and range of equivalency of the claims are included within their scope.

What is claimed is:

1. A method of changing clock frequency, the method comprising:
providing, by a first semiconductor device, a system clock signal at a first frequency and a command address signal related to a clock frequency change for a second semiconductor device;
changing, by the second semiconductor device, a frequency mode based on the command address signal related to the clock frequency change after entering a low power mode; and
providing, by the first semiconductor device, the system clock signal at a second frequency to the second semiconductor device.

2. The method according to claim 1, wherein the command address signal related to the clock frequency change comprises information related to a target frequency of the system clock signal.

3. The method according to claim 2, further comprising temporarily storing, by the second semiconductor device, the information related to the target frequency of the system clock signal after the first semiconductor device provides the command address signal related to the clock frequency change.

4. The method according to claim 1, further comprising providing, by the first semiconductor device, the command address signal related to the entry of the low power mode to the second semiconductor device before the second semiconductor device enters the low power mode.

5. The method according to claim 1, further comprising providing, by the first semiconductor device, the command address signal related to termination of the low power mode to the second semiconductor device substantially simultaneously with the system clock signal at the second frequency from the first semiconductor device to the second semiconductor device.

6. The method according to claim 1, wherein the second semiconductor device comprises a clock driver configured to buffer the system clock signal by operating in one of a high frequency mode and a low frequency mode; and
wherein changing the frequency mode comprises setting the clock driver to one of the high frequency mode and the low frequency mode.

7. The method according to claim 1, wherein the low power mode comprises at least one of a self-refresh sleep mode and a sleep mode.

8. The method according to claim 7, wherein, when the low power mode is terminated, the second semiconductor device enters a self-refresh mode from the self-refresh sleep mode or an idle mode from the sleep mode.

9. A semiconductor device comprising:
an internal clock generation circuit configured to receive a system clock signal, configured to operate in one of a high frequency mode and a low frequency mode based on a frequency mode signal, and configured to generate a command clock signal from the system clock signal;
a command address control circuit configured to receive a command address signal, configured to generate the frequency mode signal based on the command address signal, and configured to generate the frequency mode signal after the semiconductor device enters a low power mode.

10. The semiconductor device according to claim 9, wherein the internal clock generation circuit is configured to buffer the system clock signal, is configured to operate in the high frequency mode when the frequency mode signal is enabled, and is configured to operate in the low frequency mode when the frequency mode signal is disabled.

11. The semiconductor device according to claim 9, wherein the internal clock generation circuit comprises:
a clock receiver configured to receive the system clock signal;
a clock driver configured to one of the high frequency mode and the low frequency mode based on the frequency mode signal and to generate a buffered clock signal by buffering the system clock signal received through the clock receiver; and
a command clock generation circuit configured to generate the command clock signal by dividing a frequency the buffered clock signal according to a first division ratio.

12. The semiconductor device according to claim 11, wherein the internal clock generation circuit further comprises a data clock generation circuit configured to generate a data clock signal by dividing a frequency of the buffered clock signal according to a second division ratio.

13. The semiconductor device according to claim 9, wherein the low power mode comprises at least one of a self-refresh sleep mode and a sleep mode.

14. The semiconductor device according to claim 9, wherein the command address control circuit is configured to:
generate a mode register setting signal and a low power mode entry signal such that the semiconductor device enters the low power mode in response to decoding the command address signal;
store the command address signal as frequency setting information based on the mode register setting signal; and
generate the frequency mode signal from the frequency setting information based on the low power mode entry signal.

15. The semiconductor device according to claim 14, wherein:
the command address control circuit is further configured to generate a low power mode termination signal that terminates the low power mode in response to decoding the command address signal, and
the semiconductor device is configured to one of enter a self-refresh mode from the self-refresh sleep mode and enter an idle mode from the sleep mode based on the low power mode termination signal.

16. The semiconductor device according to claim 9, wherein the command address control circuit comprises:
a command address receiver configured to receive the command address signal;
a command decoder configured to generate a mode register setting signal and a low power mode entry signal such that the semiconductor device enters the low power mode in response to decoding the command address signal received through the command address receiver;
a mode register circuit configured to store the command address signal as frequency setting information based on the mode register setting signal and output the frequency setting information based on the low power mode entry signal; and
a frequency control circuit configured to generate the frequency mode signal based on the frequency setting information.

17. The semiconductor device according to claim 16, wherein the mode register circuit comprises:
a sub-register circuit configured to store the command address signal based on the mode register setting signal; and
a main register circuit configured to update the frequency setting information based on the command address signal stored in the sub-register circuit based on the low power mode entry signal.

18. A semiconductor device comprising:
an internal clock generation circuit configured to receive a system clock signal and to generate a command clock signal from the system clock signal in response to operating in one of a high frequency mode and a low frequency mode; and
a command address control circuit configured to receive the command address signal related to a clock frequency change, configured to change a frequency mode of the internal clock generation circuit, and configured to delay frequency mode change time of the internal clock generation circuit until the semiconductor device enters a low power mode.
